(19) United States
(12) Patent Application Publication
(10) Pub. No.: US 2007/0007520 A1
(43) Pub. Date: Jan. 11, 2007

(54) Display substrate, method of manufacturing the same and display apparatus having the same

(75) Inventor: Jong-Hyun Seo, Seoul (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd., Suwon-si (KR)

(21) Appl. No.: 11/280,591

(22) Filed: Nov. 15, 2005

(30) Foreign Application Priority Data
Jul. 5, 2005 (KR) 2005-60043

(51) Int. Cl. H01L 23/58

(52) U.S. Cl. 257/48

(57) ABSTRACT

A display substrate includes a plastic substrate, a gate wiring, a gate insulation layer, an active layer, a data wiring and a drain wiring. The gate wiring includes a gate line and a gate electrode portion that is electrically connected to the gate line. The active layer is formed on a portion of the gate insulation layer. The data wiring includes a data line and a repair line that is electrically connected to the data line. The drain wiring is formed on a portion between the data line and the repair line. Therefore, an opening problem induced by a fine crack of the plastic substrate may be solved.

### CROSS REFERENCE TO RELATED APPLICATIONS

This application claims priority from Korean Patent Application No. 2005-60043 filed on Jul. 5, 2005, the contents of which are herein incorporated by reference in their entirety.

### BACKGROUND OF THE INVENTION

1. Field of the Invention

The present invention relates to a display substrate, a method of manufacturing the display substrate and a display apparatus utilizing the display substrate. More particularly, the present invention relates to a display substrate capable of reducing driving errors caused by cracks in the data lines, a method of manufacturing the display substrate, and a display apparatus utilizing the display substrate.

2. Description of the Related Art

Many electronic devices such as mobile phones, digital cameras, notebook computers, monitors, etc. employ a display apparatus. Examples of such display apparatuses include a liquid crystal display (LCD) apparatus and an organic light emitting (OLED) device.

The LCD and the OLED both include a display substrate wherein each pixel can be independently driven. The display substrate includes an insulation substrate, signal wirings and a driving device such as a thin film transistor (TFT) formed on the insulation substrate.

A glass substrate has been employed as a conventional insulation substrate. However, a plastic substrate that is flexible may be employed as the insulation substrate in order to reduce its weight and thickness.

Generally, the plastic substrate includes a base substrate, a first barrier layer and a second barrier layer. The first and second barrier layers are essentially formed on the upper and lower faces of the base substrate, respectively, in order to prevent moisture or gas from infiltrating into the base substrate and diffusing into the base substrate.

However, when the plastic substrate is employed as the insulation substrate, fine cracks may develop when forming signal wirings and thin film transistor (TFT) switching devices. The fine cracks are induced by a difference between the thermal expansion coefficient of the base substrate and the thermal expansion coefficient of the barrier layer. The fine crack can have a diameter from about 30 μm to a bout 50 μm. The fine crack induces an opening of the data line that is formed on the display device, so that the display substrate is not driven.

### SUMMARY OF THE INVENTION

The present invention provides a display substrate capable of reducing a driving error caused by an opening of the data line.

The present invention also provides a method of manufacturing the above display substrate.

The present invention also provides a display apparatus having the above-mentioned display substrate.

In one aspect of the present invention, the display substrate includes a plastic substrate, a gate wiring, a gate insulation layer, an active layer, a data wiring and a drain wiring. The gate wiring is formed on the plastic substrate along a first direction. The gate wiring includes a gate line, and a gate electrode portion that is electrically connected to the gate line. The gate insulation layer is formed on the plastic substrate having the gate wiring formed thereon. The active layer is formed on a portion of the gate insulation layer, and the portion of the insulation layer corresponds to the gate electrode portion. The data wiring includes a data line and a repair line. The data line is formed on the gate insulation layer so as to cross the gate line along a second direction that is different from the first direction. The repair line is substantially parallel to the data line and is electrically connected to the data line. The drain wiring is formed on a portion between the data line and the repair line. The data wiring may include a connection line that electrically connects the data line and the repair line with each other.

In another aspect of the present invention, there is provided a method of manufacturing a display substrate. In the above method, a gate wiring is formed on a plastic substrate along a first direction. The gate wiring includes a gate line and a gate electrode portion. A gate insulation layer is formed on the plastic substrate having the gate wiring formed thereon. An active layer is formed on a portion of the gate insulation layer. The portion of the insulation layer corresponds to the gate electrode portion. A data wiring is formed on the gate insulation layer along a second direction that is different from the first direction. The data wiring includes a data line, a repair line formed substantially parallel to the data line, and a connection line that electrically connects the data line and the repair line. A drain wiring is formed on a portion between the data line and the repair line.

In still another aspect of the present invention, a display apparatus includes a first substrate, a second substrate facing the first substrate and a liquid crystal layer disposed between the first and second substrates. The first substrate includes a plastic substrate, a gate wiring, a gate insulation layer, an active layer, a data wiring and a drain wiring. The gate wiring is formed on the plastic substrate along a first direction. The gate wiring includes a gate line and a gate electrode portion that is electrically connected to the gate line. The gate insulation layer is formed on the plastic substrate having the gate wiring formed thereon. The active layer is formed on a portion of the gate insulation layer, and the portion of the insulation layer corresponds to the gate electrode portion. The data wiring includes a data line and a repair line. The data line is formed on the gate insulation layer so as to cross the gate line along a second direction that is different from the first direction. The repair line is substantially parallel to the data line and is electrically connected to the data line. The drain wiring is formed on a portion between the data line and the repair line. The data wiring may include a connection line that electrically connects the data line and the repair line with each other.

According to the above, the problem of openings induced by fine cracks in the plastic substrate may be solved. As a result, driving errors the data lines are prevented, so that the display quality of the display device is improved.

### BRIEF DESCRIPTION OF THE DRAWINGS

The above and other features and advantages of the present invention will become more apparent with reference to the accompanying drawings, in which:

FIG. 1 is a layout illustrating a portion of a display substrate according to an embodiment of the present invention;

FIG. 2 is a cross-sectional view taken along a line 1-1′ in FIG. 1;

FIG. 3 is a cross-sectional view illustrating the plastic substrate according to an example embodiment;

FIGS. 4 through 7 are cross-sectional views illustrating a method of manufacturing the display substrate in FIGS. 1 and 2; and

FIG. 8 is a cross-sectional view illustrating a display apparatus according to an embodiment of the present invention.

### DESCRIPTION OF THE EMBODIMENTS

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the a rt. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be explained in detail with reference to the accompanying drawings.

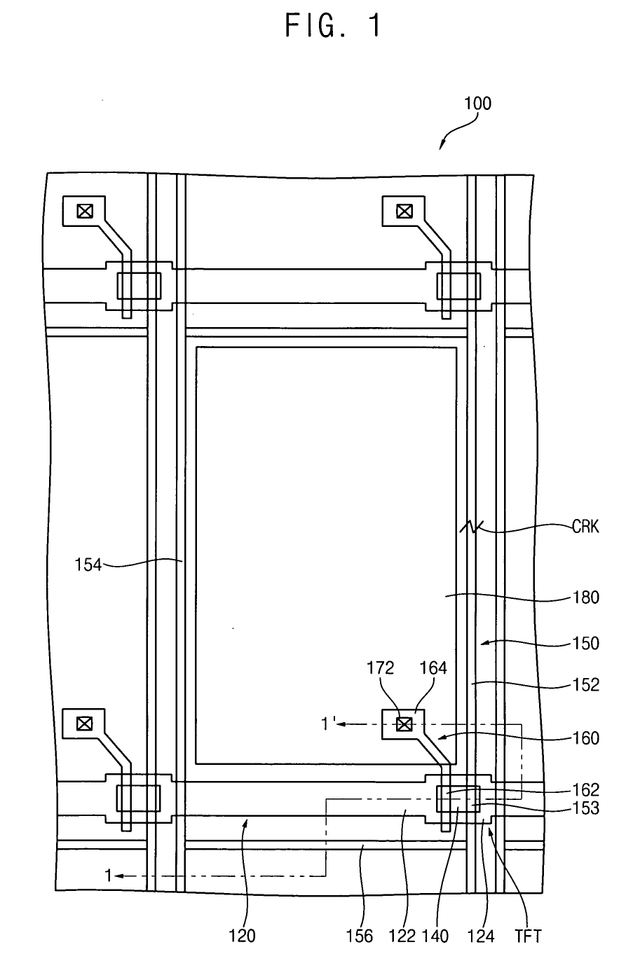

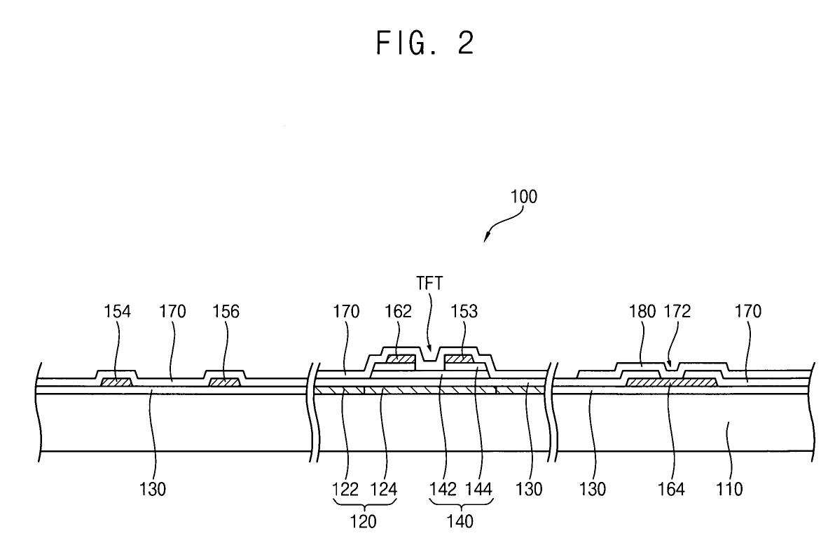

FIG. 1 is a layout illustrating a portion of a display substrate according to an example embodiment of the present invention, and FIG. 2 is a cross-sectional view taken along a line 1-1′ in FIG. 1.

Referring to FIGS. 1 and 2, a display substrate 100 includes a plastic substrate 110, gate wiring 120, a gate insulation layer 130, an active layer 140, data wiring 150 and drain wiring 160.

The plastic substrate 110 has a flexible thin-film shape. The plastic substrate 110 includes a synthetic resin that is optically transparent.

The gate wiring 120 is formed on the plastic substrate 110. The gate wiring 120 includes a gate line 122 and a gate electrode portion 124. The gate electrode portion 124 is electrically connected to the gate line 122.

The gate wiring 120 is extended along a first direction. The gate electrode portion 124 is electrically connected to the gate line 122, and the gate electrode portion 124 is an element of a switching device TFT.

The gate insulation layer 130 is formed on the plastic substrate 110 having the gate wiring 120 formed thereon. The gate insulation layer 130 includes, for example, silicon nitride (SiNx), silicon oxide (SiOx), etc.

The active layer 140 is formed on portions of the gate insulation layer 130 corresponding to the gate electrode portions 124. The active layer 140 includes a semiconductor layer 142 and an ohmic contact layer 144. The semiconductor layer 142 includes amorphous silicon (a-Si). The ohmic contact layer 144 includes amorphous silicon (n+a-Si) having n-type dopant.

The data wiring 150 is formed on the gate insulation layer 130. The data wiring 150 includes a data line 152 and a repair line 154. The data line 152 and the repair line 154 are extended along a second direction that is different from the first direction. For example, the first direction is substantially perpendicular to the second direction, so that the data line 152 and the repair line 154 are substantially perpendicular to the gate wiring 120 that is extended along the first direction.

The data line 152 includes a source electrode portion 153 formed on the active layer 140. The source electrode portion 153 is an element of the switching device TFT.

The data wiring 150 may further include a connection line 156. The connection line 156 electrically connects the data line 152 to the repair line 154. The connection line 156 is formed substantially parallel to the gate wiring 120. For example, the connection line 156 is formed on a portion adjacent to the gate wiring 120 in order to prevent decreasing the aperture ratio of the display substrate 100.

The drain wiring 160 is formed on the gate insulation layer 130. The drain wiring 160 is disposed between the data line 152 and the repair line 154. The drain wiring 160 includes a drain electrode portion 162 that is disposed on the active layer 140. The drain electrode portion 162 is an element of the switching device TFT.

The source electrode portion 153 and the drain electrode portion 162 are spaced apart from each other over the active layer 140. The active layer 140 corresponds to a channel of the switching device TFT.

The drain wiring 160 further includes a contact portion 164 that is electrically connected to a pixel electrode 180. The data wiring 150 and the drain wiring 160 include substantially the same material. The data wiring 150 and the drain wiring 160 are formed through the same process.

The display substrate 100 may further include a protection layer 170 and a pixel electrode 180. The protection layer 170 is formed on the gate insulation layer 130 having the data wiring 150 and the drain wiring 160 formed thereon. A contact hole 172 is formed through the protection layer 170. The contact hole 172 exposes the contact portion 164 of the drain wiring 160.

The pixel electrode 180 is formed on the protection layer 170 such that the pixel electrode 180 at least partially overlaps the contact portion 164 of the drain wiring 160 when viewed from a plan view of the display substrate.

The pixel electrode 180 includes an optically transparent and electrically conductive material. For example, the pixel electrode 180 includes indium tin oxide (ITO), indium zinc oxide (IZO), etc.

The pixel electrode 180 is electrically connected to the contact portion 164 of the drain wiring 160 through the contact hole 172.

Although not shown, the display substrate 100 optionally includes an organic layer disposed between the protection layer 170 and the pixel electrode 180 in order to planarize a surface of the display substrate 100.

The display substrate 100 according to the present invention employs the plastic substrate 110 having a barrier layer, so that a fine crack may occur in the plastic substrate 110 during processes of forming the display substrate 100. The fine crack may cause an opening of the data line 152.

To address this problem, the display substrate 100 according to the present invention further includes a repair line 154 that forms an alternate electrical path to the data line 152.

In conventional displays, when a crack CRK in the data line 152 is formed, the data line 152 is unable to deliver an electrical signal from the driver (not shown) to the source electrode 153 of the TFT. According to the present invention, however, the electrical signal from the driver is transmitted via the repair line 154 to connection line 156 back to the data line 152 to the source electrode 153, thereby bypassing the crack CRK. The present invention thus employs parallel electrical paths to maintain an electrical connection to a TFT electrode in case a crack CRK open-circuits one of the paths.

In FIGS. 1 and 2, the display substrate 100 includes a repair line electrically connected to the data line 152 to bypass a crack in the data line 152. The same technique may be applied to address cracks in the gate line 122. In detail, the display substrate 100 may further include the repair line that is electrically connected to the gate line in order to solve an opening problem of the gate line 122. Additionally, the display substrate 100 may include both first repair lines for solving the opening problem of the data line 152, and second repair lines for solving the opening problem of the gate line 122.

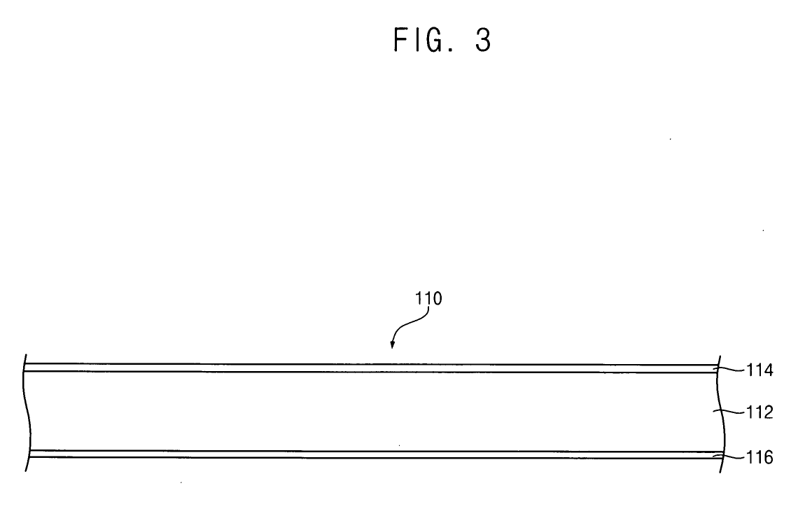

FIG. 3 is a cross-sectional view illustrating the plastic substrate according to an embodiment of the invention.

Referring to FIG. 3, the plastic substrate 110 includes a base substrate 112, a first barrier layer 114 and a second barrier layer 116. The first barrier layer 114 is formed on an upper face of the base substrate 112. The second barrier layer 116 is formed on a lower face of the base substrate 112.

The base substrate 112 includes a synthetic resin that is optically transparent. The base substrate 112 includes, for example, a resin such as polyethersulfone (PES), polycarbonate (PC), polyimide (PI), polyethylene naphthelate (PEN), polyethylene terephthalate (PET), etc.

The first and second barrier layers 114 and 116 are formed on the upper and lower faces of the base substrate 112, respectively, in order to prevent moisture or gas from infiltrating and diffusing into the base substrate 112.

Each of the first and second barrier layers 114 and 116 includes a material having a thermal expansion coefficient that is smaller than that of the base substrate 116. The first and second barrier layers 114 and 116 include, for example, an acryl based resin.

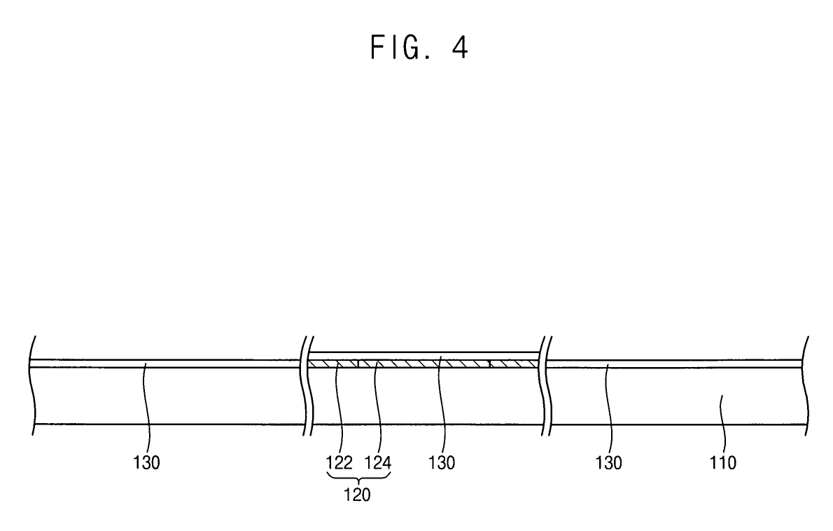

Hereinafter, a method of manufacturing display substrate according to the present invention will be explained with reference to FIGS. 4 through 7.

FIGS. 4 through 7 are cross-sectional views illustrating a method of manufacturing the display substrate in FIGS. 1 and 2.

Referring to FIGS. 1 and 4, a first metal layer (not shown) is formed on the plastic substrate 110, and then the first metal layer is patterned to form the gate wiring 120 including the gate line 122 and the gate electrode portion 124 through a photolithography process.

The gate wiring 120 is extended along the first direction (or horizontal direction). The gate electrode portion 124 is electrically connected to the gate line 122. The gate electrode portion 124 is an element of the switching device TFT. The gate wiring 120 has, for example, a three-layered structure including molybdenum/aluminum/molybdenum layers.

The gate insulation layer 130 is formed on the plastic substrate 110 having the gate wiring 120 formed thereon. The gate insulation layer 130 includes, for example, silicon nitride (SiNx) or silicon oxide (SiOx).

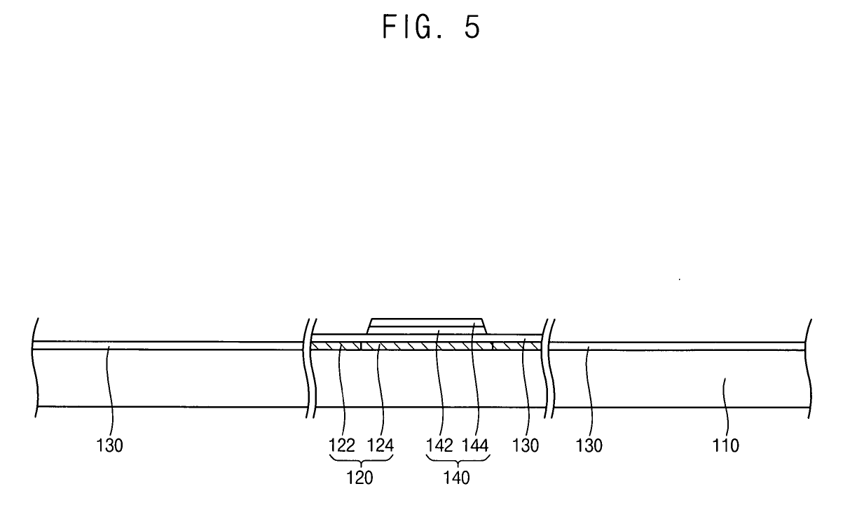

Referring to FIGS. 1 and 5, an a-Si layer for forming the semiconductor layer is formed on the gate insulation layer 130, and an n+a-Si layer for forming the ohmic contact layer is formed on the a-Si layer. The a-Si layer and the n+a-Si layer are patterned by using, for example, a photolithographic process, to thereby form the active layer 140 disposed over the gate electrode portions 124.

The active layer 140 includes a semiconductor layer 142 and an ohmic contact layer 144. The semiconductor layer 142 includes a-Si. The ohmic contact layer 144 includes n+a-Si that is heavily doped with an n-type impurity.

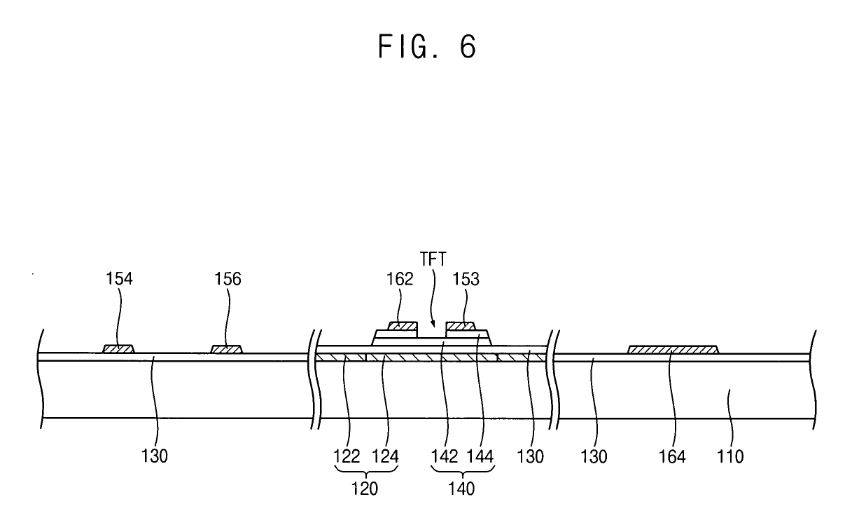

Referring to FIGS. 1 and 6, when a second metal layer (not shown) is formed on the gate insulation layer 130 and the active layer 140, and the second metal layer is patterned to form the data wiring 150 and the drain wiring 160 by using, for example, a photolithographic process.

The data wiring 150 includes a data line 152, a repair line 154 that is formed substantially parallel to the data line 154, and a connection line 156 that electrically connects the data line 152 to the repair line 154. The data line 152 includes a source electrode portion 153 that at least partially overlaps the active layer 140.

The data line 152 and the repair line 154 extend along the second direction (or vertical direction) that is substantially perpendicular to the first direction. The connection line 156 is formed substantially parallel to the gate wiring 120 to connect the data line 152 to the repair line 154. In order to prevent the decreasing of an aperture ratio of the display 100, the connection line 156 is formed on a portion adjacent to the gate wiring 120.

The drain wiring 160 is disposed between the data line 152 and the repair line 154. The drain-wiring 160 includes the drain electrode portion 162 that is disposed on the active layer 140, and the contact portion 164 that is disposed on the gate insulation 130.

A source electrode portion 153 of the data wiring 150 is an element of the switching device TFT. A drain electrode portion 162 of the drain wiring 160 is an element of the switching device TFT. The source electrode portion 153 and the drain electrode portion 162 are spaced apart from each other. The source electrode portion 153 and the drain electrode portion 162 are disposed over the active layer 140, so that currents may flow between the source electrode portion 153 and the drain electrode portion 162 through the active layer 140. The active layer 140 corresponds to a channel of the switching device TFT.

The data wiring 150 and the drain wiring 160 include a same material. The data wiring 150 and the drain wiring 160 are simultaneously formed through the same process. The data wiring 150 and the drain wiring 160 have, for example, a three-layered structure including molybdenum/aluminum/molybdenum layers.

Thereafter, the ohmic contact layer 144 disposed between the source electrode portion 153 and the drain electrode portion 162 is removed to expose the semiconductor layer 142.

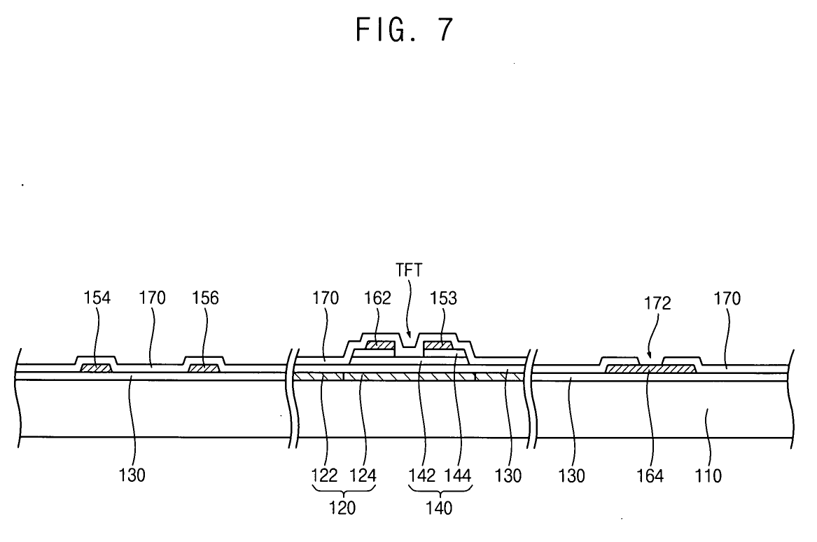

Referring to FIGS. 1 and 7, the protection layer 170 is formed on the gate insulation layer 130 having the data wiring 150 and the drain wiring 160 formed thereon, and then a portion of the protection layer 170 is removed to form the contact hole 172 that exposes a portion of the contact portion 164 of the drain wiring 160.

Referring again to FIGS. 1 and 2, a transparent and conductive layer (not shown) is formed on the protection layer 170, and the transparent and conductive layer is patterned to form the pixel electrode 180. The pixel electrode 180 includes an optically transparent and electrically conductive material. The pixel electrode 180 includes, for example, indium tin oxide (ITO), indium zinc oxide (IZO), etc.

The pixel electrode 180 is electrically connected to the contact portion 164 of the drain wiring 160 through the contact hole 172 formed at the protection layer 170.

In addition, the manufacturing of the display substrate 100 according to the present invention may further include a step of forming an organic layer (not shown) disposed between the protection layer 170 and the pixel electrode 180 in order to planarize a surface of the display substrate 100.

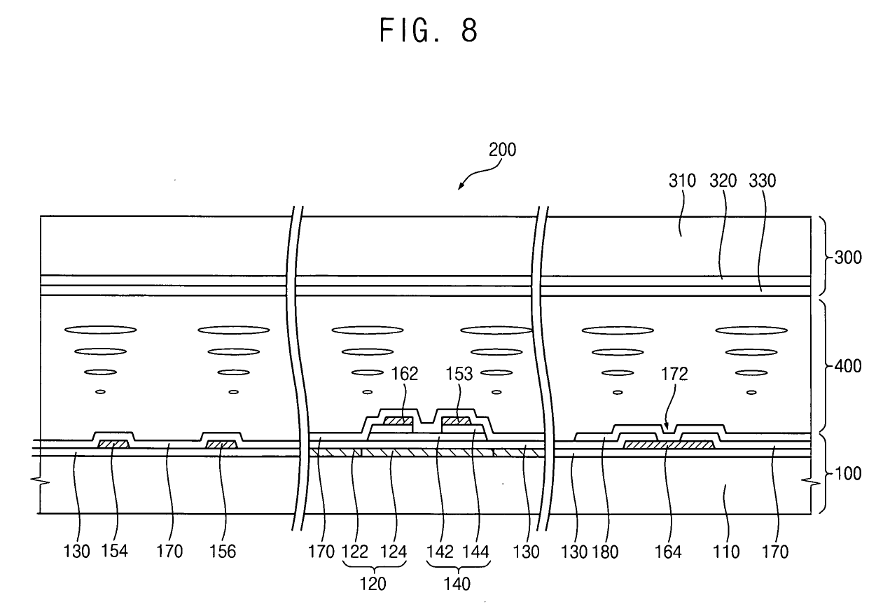

FIG. 8 is a cross-sectional view illustrating a display apparatus according to an example embodiment of the present invention. The display substrate of the present embodiment has the same structure as shown in FIG. 2. Thus, the same reference numerals will be used to refer to the same or like parts as those described in FIG. 2 and any further explanation concerning the above elements will be omitted.

Referring to FIG. 8, a display apparatus 200 according to an example of the present invention includes a display substrate 100, a color filter substrate 300 facing the display substrate 100 and a liquid crystal layer 400 disposed between the display substrate 100 and the color filter substrate 300.

The color filter substrate 300 includes a plastic substrate 310, a color filter layer 320 and a common electrode 330.

The plastic substrate 310 has a flexible thin film shape. The plastic substrate 310 includes an optically transparent resin. The plastic substrate 310 includes, for example, polyethersulfone (PES).

The color filter layer 320 is formed on a face of the plastic substrate 310, which faces the display substrate 100. The color filter layer 320 includes a red color filter, a green color filter and a blue color filter. The color filter layer 320 may be formed on the display substrate 100.

The common electrode 330 is formed on the color filter layer 320 such that the common electrode 330 faces the display substrate 100. The common electrode 330 includes an optically transparent and electrically conductive material. The common electrode 330 includes, for example, indium tin oxide (ITO), indium zinc oxide (IZO), etc.

The liquid crystal layer 400 includes liquid crystal molecules arranged regularly. The liquid crystal layer 400 has anisotropy of refractive index and dielectric coefficient. When electric fields are applied to the liquid crystal layer 400, an arrangement of the liquid crystal layer 400 is altered to control optical transmittance.

When a gate signal is applied to the gate electrode portion 124 through the gate line 122, the switching device TFT is turned-on. A data signal of the data line 152 is applied to the pixel electrode 180 through the source electrode portion 153 and the drain electrode portion 162. In addition, a common voltage is applied to a common electrode 330 of the color filter substrate 300.

Therefore, electric fields are generated between the pixel electrode 180 and the common electrode 330. When the electric fields are applied to the liquid crystal disposed between the pixel electrode 180 and the common electrode 330, liquid crystal molecules of the liquid crystal layer 400 are rearranged to change optical transmittance to display predetermined images.

According to the display substrate, a method of manufacturing the display substrate and a display apparatus having the display substrate, the repair line that is electrically connected to the data line is formed on each pixel area in order to solve the opening problem of the data line.

Therefore, the opening problem of the data line, which may be induced by fine cracks of the plastic substrate, may be solved by the repair line without additional process for solving the opening problem of the data line.

Having described the example embodiments of the present invention and its advantages, it is noted that various changes, substitutions and alterations can be made herein without departing from the spirit and scope of the invention as defined by appended claims.

What is claimed is:

1. A display substrate comprising:
a plastic substrate;
a gate wiring formed on the plastic substrate along a first direction, the gate wiring including a gate line and a gate electrode portion electrically connected to the gate line;
a gate insulation layer formed on the plastic substrate having the gate wiring formed thereon;
an active layer formed on a portion of the gate insulation layer corresponding to the gate electrode portion;
a data wiring including a data line formed on the gate insulation layer so as to cross the gate line along a second direction that is different from the first direction and a repair line that is substantially parallel to the data line and is electrically connected to the data line; and
a drain wiring formed on a portion between the data line and the repair line.

2. The display substrate of claim 1, wherein the data wiring further comprises a connection line that electrically connects the data line and the repair line with each other.

3. The display substrate of claim 2, wherein the connection line is formed substantially parallel to the gate line.

4. The display substrate of claim 1, wherein the data line comprises a source electrode portion that at least partially overlaps the active layer, and
the drain wiring comprises a drain electrode portion that at least partially overlaps the active layer.

5. The display substrate of claim 1, further comprising:
a protection layer that is formed on the gate insulation layer having the gate wiring and drain wiring formed thereon; and
a pixel electrode formed on the protection layer.

6. The display substrate of claim 5, wherein the drain wiring further comprises a contact portion that is electrically connected to the pixel electrode.

7. The display substrate of claim 6, wherein the pixel electrode is electrically connected to the contact portion through a contact hole formed at the protection layer.

8. The display substrate of claim 1, wherein the plastic substrate comprises:
a base substrate; and
barrier layers formed on lower and upper faces of the base substrate.

9. The display substrate of claim 8, wherein the base substrate comprises a material selected from the group consisting of polyethersulfone (PES), polycarbonate (PC), polyimide (PI), polyethylene naphthalate (PEN) and polyethylene terephthalate (PET).

10. The display substrate of claim 8, wherein the barrier layers comprise an acryl based resin.

11. A method of manufacturing a display substrate, comprising:
forming a gate wiring on a plastic substrate along a first direction, the gate wiring including a gate line and a gate electrode portion;
forming a gate insulation layer on the plastic substrate having the gate wiring formed thereon;
forming an active layer on a portion of the gate insulation layer corresponding to the gate electrode portion;
forming a data wiring on the gate insulation layer along a second direction that is different from the first direction, the data wiring including a data line, a repair line formed substantially parallel to the data line, and a connection line that electrically connects the data line to the repair line; and
forming a drain wiring on a portion between the data line and the repair line.

12. The method of claim 11, wherein the data line and repair line are formed along the second direction, and
the connection line is formed substantially parallel to the gate line.

13. The method of claim 11, wherein forming the data line comprises forming a source electrode portion that at least partially overlaps the active layer, and
forming the drain wiring comprises forming a drain electrode portion that at least partially overlaps the active layer.

14. The method of claim 11, further comprising:
forming a protection layer on the gate insulation layer having the data wiring and the drain wiring formed thereon; and
forming a pixel electrode layer on the protection layer.

15. The method of claim 14, wherein the drain wiring further comprises a contact portion that is electrically connected to the pixel electrode layer.

16. The method of claim 11, wherein the data wiring and the drain wiring are simultaneously formed from a same metal layer.

17. The method of claim 11, wherein the plastic substrate comprises:
a base substrate; and
a barrier layer formed on the base substrate.

18. A display apparatus comprising:
a first substrate;
a second substrate facing the first substrate; and
a liquid crystal layer disposed between the first and second substrate,
wherein the first substrate includes:
a plastic substrate;
a gate wiring formed on the plastic substrate along a first direction, the gate wiring including a gate line and a gate electrode portion that is electrically connected to the gate line;
a gate insulation layer formed on the plastic substrate having the gate wiring formed thereon;
an active layer formed on a portion of the gate insulation layer corresponding to the gate electrode portion;
a data wiring including a data line formed on the gate insulation layer so as to cross the gate line along a second direction that is different from the first direction and a repair line parallel to the data line and electrically connected to the data line; and
a drain wiring formed on a portion between the data line and the repair line.

19. The display apparatus of claim 18, wherein the data wiring further comprises a connection line, the connection line electrically connecting the data line and the repair line with each other.

20. The display apparatus of claim 18, wherein the first substrate comprises:
a base substrate; and
barrier layers formed on upper and lower faces of the base substrate.

21. The display apparatus of claim 20, wherein the second substrate comprises:
a second plastic substrate; and
a common electrode layer formed on the second plastic substrate such that the common electrode layer faces the pixel electrode layer.

22. The display apparatus of claim 18, wherein the first substrate comprises:
a protection layer formed on the gate insulation layer having the data wiring and the drain wiring formed thereon; and
a pixel electrode layer formed on the protection layer.

23. A display substrate comprising:
a plastic substrate;
a first wiring formed on the plastic substrate along a first direction, the first wiring comprising a first portion and a second portion; and
a second wiring formed on the plastic substrate, the second wiring electrically connected to the first wiring at the first portion and at the second portion.

24. The display substrate of claim 23, further comprising:
a third wiring formed on the plastic substrate along a second direction.

25. The display substrate of claim 24, wherein:
the first wiring is a data line;
the second wiring is a repair line;
the third wiring is a gate wiring;
the data line is substantially parallel to at least a portion of the repair line; and
the first direction is substantially perpendicular to the second direction.

26. The display substrate of claim 25, further comprising:
a gate insulation layer formed on the plastic substrate having the gate wiring formed thereon;
a gate electrode portion of the gate wiring; and
an active layer formed on the gate electrode portion.

27. The display substrate of claim 24, wherein:
the first wiring is a gate wiring;
the second wiring is a repair line;
the third wiring is a data line;
the gate wiring is substantially parallel to at least a portion of the repair line; and
the first direction is substantially perpendicular to the second direction.
